(19) United States
(12) Patent Application Publication
(10) Pub. No.: US 2023/0410785 A1
(43) Pub. Date: Dec. 21, 2023

(54) SONIC WAVE GENERATOR

(71) Applicant: Nippon Telegraph and Telephone Corporation, Tokyo (JP)

(72) Inventors: Naoki Miura, Tokyo (JP); Hiroaki Taguchi, Tokyo (JP); Hideyuki Nosaka, Tokyo (JP); Takeshi Komatsu, Tokyo (JP)

(21) Appl. No.: 18/253,875

(22) PCT Filed: Dec. 2, 2020
(86) PCT No.: PCT/JP2020/044821

§ 371 Date: May 22, 2023

(51) Int. Cl. G10K 15/04; G10K 11/34; G10K 9/12

(52) U.S. Cl. CPC G10K 15/04; G10K 11/341; G10K 9/12

(57) ABSTRACT

A sound wave generator is configured to generate ultrasonic waves having a predetermined frequency that chases away vermin. The sound wave generator includes a power supply, a switch, an oscillation circuit, and a speaker. The power supply includes a battery that is a DC power supply and outputs DC power for generating sound waves. The switch is operated by a user of the sound wave generator to switch between supply and non-supply of power from the power supply to the oscillation circuit. When the switch is turned on, the oscillation circuit operates with DC power output from the power supply and oscillates an electrical signal having a predetermined frequency. An organic transistor is used in the oscillation circuit. The speaker converts the electrical signal oscillated by the oscillation circuit into sound waves and outputs the sound waves.

### CROSS-REFERENCE TO RELATED APPLICATIONS

This application is a national phase entry of PCT Application No. PCT/JP2020/044821, filed on Dec. 2, 2020, which application is hereby incorporated herein by reference.

### TECHNICAL FIELD

The present invention relates to a sound wave generator that generates sound waves such as ultrasonic waves.

### BACKGROUND

In recent years, as disclosed in Patent Literature 1 and Non Patent Literature 1, vermin repelling devices that generate ultrasonic waves to chase away vermin have been developed. The vermin repelling device generates sound waves having a high frequency audible only to the vermin at a high sound pressure and applies stress to the vermin, thereby driving the vermin out of the place. The vermin repelling device using ultrasonic waves is useful and has little influence on the human body and the environment.

### CITATION LIST

### Patent Literature

Patent Literature 1: JP 2008-11777 A

### Non Patent Literature

Non Patent Literature 1: “2018 Environmental report,” page 7, [online], NTT Service Innovation Laboratory, etc., [Retrieved on Nov. 20, 2020], Internet <URL:https://www.ntt.co.jp/RD/environment/pdf/rep2018.pdf>

### SUMMARY

### Technical Problem

In the vermin repelling device, a transistor is used in an oscillation circuit for generating sound waves. However, a rare metal having a high environmental load may be used as a semiconductor material of the transistor during mining and/or smelting. For this reason, also in the vermin repelling device, the environmental load due to the use of the rare metal becomes a problem. Such a problem is also applicable to a general sound wave generator.

An embodiment of the present invention provides a sound wave generator having a low environmental load.

### Solution to Problem

In order to solve the above-described problems, according to embodiments of the present invention, there is provided a sound wave generator including: an oscillation circuit configured to oscillate an electrical signal for sound waves; and a speaker configured to convert the electrical signal oscillated by the oscillation circuit into sound waves and output the sound waves, in which one or more organic transistors using an organic semiconductor are used in the oscillation circuit.

### Advantageous Effects of Embodiments of the Invention

According to embodiments of the present invention, it is possible to provide a sound wave generator having a low environmental load.

### BRIEF DESCRIPTION OF THE DRAWINGS

FIG. 1 is a configuration diagram of a sound wave generator according to a first embodiment of the present invention.

FIG. 2 is a cross-sectional view illustrating a configuration example of a transistor used in FIG. 1.

FIG. 3 is a diagram illustrating a configuration example of an oscillation circuit and a configuration example of a speaker in FIG. 1.

FIG. 4 is a circuit diagram illustrating an example of a logic inverter.

FIG. 5 is a diagram illustrating a modification of the oscillation circuit and a configuration example of the speaker in FIG. 1.

FIG. 6 is a diagram illustrating a modification of the oscillation circuit and a configuration example of the speaker in FIG. 1.

FIG. 7 is a diagram illustrating a modification of the oscillation circuit and a configuration example of the speaker in FIG. 1.

FIG. 8 is a configuration diagram of a sound wave generator according to a second embodiment of the present invention.

FIG. 9 is a circuit diagram of an example of a DC/DC conversion circuit of FIG. 8.

FIG. 10 is a configuration diagram of a sound wave generator according to a third embodiment of the present invention.

FIG. 11 is a circuit diagram of an example of a voltage amplifier circuit of FIG. 10.

FIG. 12 is a configuration diagram of a sound wave generator according to a fourth embodiment of the present invention.

FIG. 13 is a configuration diagram of a sound wave generator.

FIG. 14 is a configuration diagram of a smartphone that operates as a sound wave generator.

### DETAILED DESCRIPTION OF ILLUSTRATIVE EMBODIMENTS

### First Embodiment

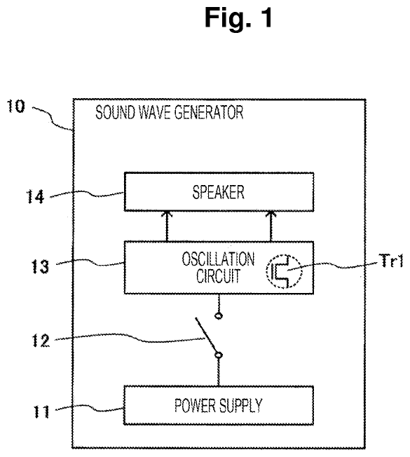

First, a sound wave generator 10 according to a first embodiment of the present invention will be described with reference to FIGS. 1 to 4. The sound wave generator 10 is configured to generate ultrasonic waves having a predetermined frequency that chases away vermin. As illustrated in FIG. 1, the sound wave generator 10 includes a power supply 11, a switch 12, an oscillation circuit 13, and a speaker 14. One of the features of the first embodiment is that one or more organic transistors Tr1 using an organic semiconductor are used in the oscillation circuit 13.

The power supply 11 includes a battery that is a DC power supply and outputs DC power for generating sound waves. The switch 12 is operated by a user of the sound wave generator 10 to switch between supply and non-supply of power from the power supply 11 to the oscillation circuit 13, that is, turns the power of the sound wave generator 10 on and off. When the switch 12 is turned on, the oscillation circuit 13 operates with DC power output from the power supply 11 and oscillates an electrical signal having a predetermined frequency for sound waves. The organic transistor Tr1 is used in the oscillation circuit 13 as described above. The speaker 14 converts the electrical signal oscillated by the oscillation circuit 13 into sound waves and outputs the sound waves.

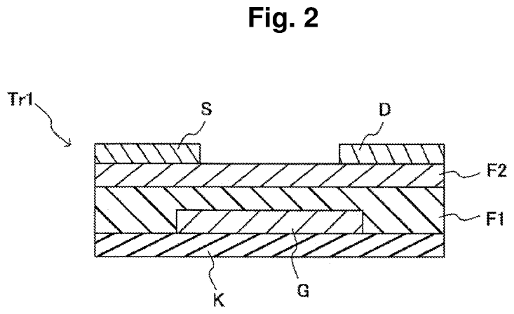

As illustrated in FIG. 2, the organic transistor Tr1 used in the oscillation circuit 13 includes a substrate K, a gate electrode G formed on the substrate K, and a gate insulating film F1 formed on the substrate K to cover the gate electrode G. The organic transistor Tr1 further includes an organic semiconductor layer F2 formed of an organic semiconductor on the gate insulating film F1 and a source electrode S and a drain electrode D formed on the organic semiconductor layer F2. The gate electrode G, the source electrode S, and the drain electrode D are formed of, for example, gold, copper, conductive carbon, or the like. The gate insulating film F1 is formed of parylene, a silicon oxide film, or the like. Examples of the material of the organic semiconductor include pentacene, naphthacene, fullerene, and a naphthalenetetracarboxylic acid diimide derivative (NTCDI). The organic transistor Tr1 is a field effect transistor in which the organic semiconductor layer F2 functions as an active layer. The configuration of the organic transistor Tr1 is not limited to the top contact type structure illustrated in FIG. 2. The organic transistor Tr1 may be, for example, a bottom contact type.

The organic transistor Tr1 includes an N-type organic transistor and a P-type organic transistor depending on whether the organic semiconductor layer F2 is N-type or P-type. Which type of organic transistor is employed as the organic transistor Tr1 used in the oscillation circuit 13 depends on the circuit configuration of the oscillation circuit 13. When the plurality of organic transistors Tr1 are used in the oscillation circuit 13, some of the plurality of organic transistors Tr1 may be N-type, and the remaining organic transistors Tr1 may be P-type.

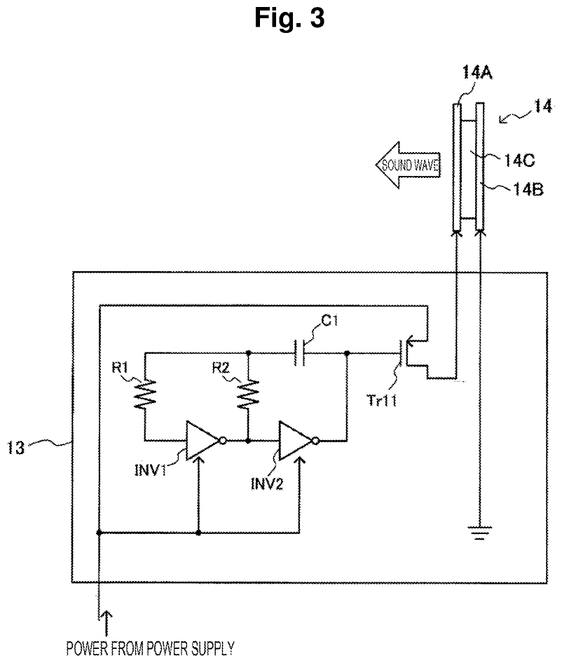

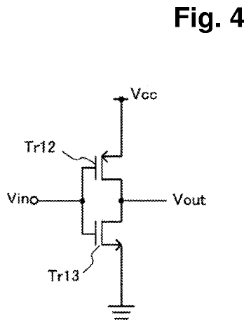

As illustrated in FIG. 3, the oscillation circuit 13 may be a phase-shift type RC oscillation circuit including resistors R1 and R2, a capacitor C1, an organic transistor Tr11, and logic inversion circuits INV1 and INV2. Each of the logic inversion circuits INV1 and INV2 includes a NOT circuit including two organic transistors Tr12 and Tr13 as illustrated in FIG. 4 and operates with DC power output from the power supply 11. Vcc in FIG. 4 is a power supply voltage of the power supply 11. The organic transistors Tr11 to Tr13 correspond to the organic transistor Tr1 illustrated in FIG. 1. The organic transistors Tr11 and Tr12 are P-type, and the organic transistor Tr13 is N-type. Note that the organic transistor Tr11 may be N-type. In this case, the connection destinations of the source and the drain are reversed.

When the DC power output from the power supply 11 is supplied to the oscillation circuit 13 illustrated in FIG. 3, the power supply voltage from the power supply 11 is applied to the logic inversion circuits INV1 and INV2 as Vcc of FIG. 4. Accordingly, the logic inversion circuits INV1 and INV2 start to operate, and a voltage signal having a frequency corresponding to each resistance value of the resistors R1 and R2 and the capacitance value of the capacitor C1 is input to the gate of the organic transistor Tr11. Accordingly, the organic transistor Tr11 is turned on and off at the above-described frequency. When the organic transistor Tr11 is turned on and off, the source and the drain of the organic transistor Tr11 become conductive or non-conductive, whereby an electrical signal having the above-described frequency as an oscillation frequency is output from the drain of the organic transistor Tr11 to the speaker 14.

As illustrated in FIG. 3, the speaker 14 includes a first electrode 14A connected to the drain of the transistor Tr3, a grounded second electrode 14B, and a film-shaped piezoelectric body 14C sandwiched between the first electrode 14A and the second electrode 14B. The first electrode 14A also functions as a diaphragm that emits vibration of the piezoelectric body 14C as sound waves. A material of the piezoelectric body 14C is arbitrary, but the piezoelectric body 14C is formed of, for example, lead zirconate titanate (PZT) or polyvinylidene fluoride (PVDF). An electrical signal from the drain of the organic transistor Tr11 is input to the first electrode 14A. A ground signal, that is, a 0 V signal, is input to the second electrode 14B. Therefore, the piezoelectric body 14C vibrates due to the electrical signal from the organic transistor Tr11. With this vibration, the first electrode 14A also functioning as a diaphragm vibrates, and as a result, sound waves having the frequency of the electrical signal are generated.

In the sound wave generator 10 according to the first embodiment, the organic transistor Tr1 is used in the oscillation circuit 13. Here, as the organic semiconductor of the organic transistor Tr1, a rare metal that is used in a conventional inorganic semiconductor and has a problem of environmental load during mining and/or smelting is not used. Therefore, the amount of rare metal used can be reduced by the amount of the organic transistor Tr1 employed, and the environmental load of the sound wave generator 10 is accordingly low. Furthermore, since the organic transistor Tr1 can be formed by printing or the like, the manufacturing process of the organic transistor Tr1 is simpler than the manufacturing process of the inorganic transistor and has a lower environmental load. This also decreases the environmental load of the sound wave generator 10. Furthermore, by forming the organic transistor Tr1 by printing, cost reduction and mass productivity improvement of the sound wave generator 10 are expected. In addition, by forming the organic transistor Tr1 into a film shape, the sound wave generator 10 can be downsized, and the portability of the sound wave generator 10 can be improved by the downsizing. Furthermore, in general, organic transistors are not good at switching at high frequencies and are suitable for use in devices that handle frequencies on the order of sound waves. Therefore, the sound wave generator 10 is a suitable use of the organic transistor.

### Modification of First Embodiment

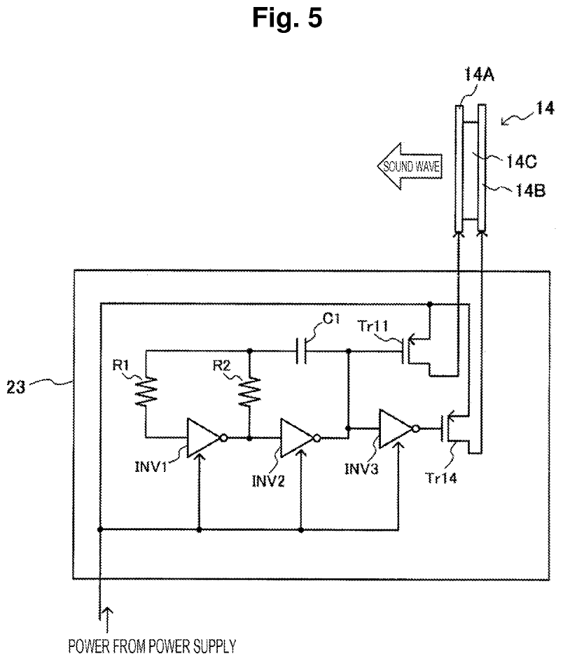

The oscillation circuit 13 may be changed to an oscillation circuit 23 like that illustrated in FIG. 5. The oscillation circuit 23 further includes an organic transistor Tr14 as the organic transistor Tr1 and a logic inversion circuit INV3 as compared with the oscillation circuit 13 of FIG. 3. The organic transistor Tr14 is P-type. The drain of the organic transistor Tr14 is connected to the second electrode 14B of the speaker 14. The logic inversion circuit INV3 is configured by, for example, the NOT circuit of FIG. 4 similarly to the logic inversion circuits INV1 and INV2. In the oscillation circuit 23, an electrical signal obtained by inverting the electrical signal from the drain of the organic transistor Tr1 is output from the drain of the organic transistor Tr14 by the logic inversion circuit INV3. Accordingly, the oscillation circuit 23 can operate the speaker 14 with the differential signal and can double the sound pressure from the speaker 14 with power equivalent to that of the oscillation circuit 13 in FIG. 3.

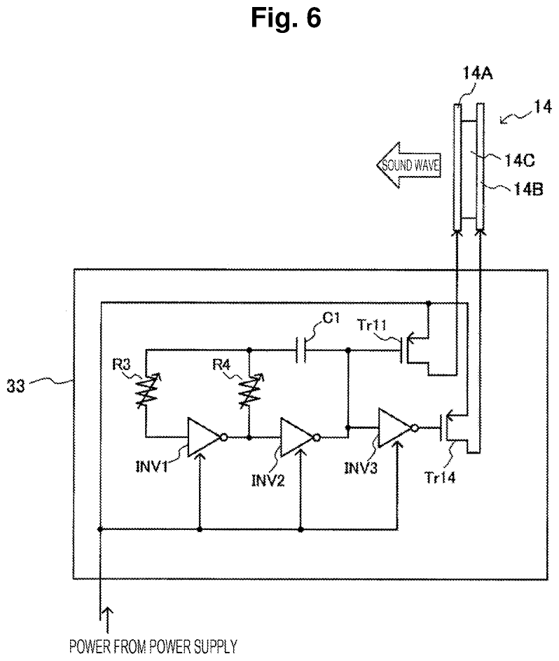

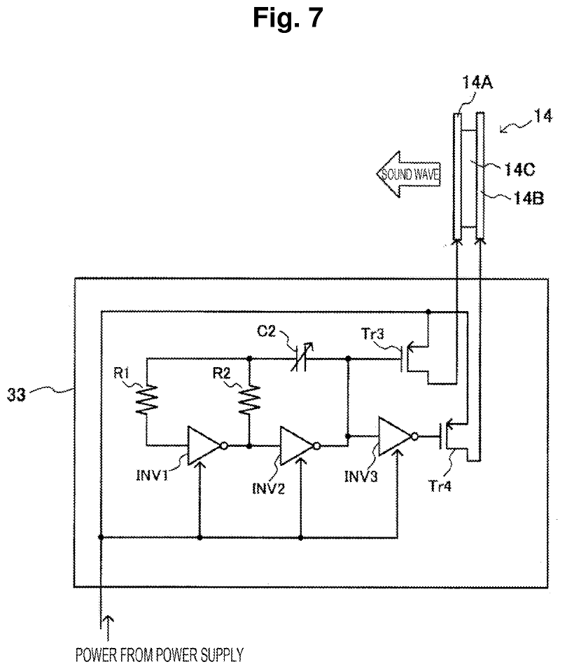

The oscillation circuit 23 illustrated in FIG. 5 may be changed to an oscillation circuit 33 illustrated in FIG. 6 or an oscillation circuit 43 illustrated in FIG. 7. The oscillation circuit 33 is a circuit in which resistors R1 and R2 of the oscillation circuit 23 are changed to variable resistors R3 and R4. The oscillation circuit 43 is a circuit in which a capacitor C1 of the oscillation circuit 23 is changed to a variable capacitance capacitor C2. With these configurations, the frequency of the electrical signal output from the oscillation circuit 33 or 43, that is, the frequency of the sound waves output from the speaker 14, can be made variable. Therefore, the frequency of the sound waves can be changed according to the application. For example, the variable resistors R3 and R4 or the variable capacitance capacitor C2 may be provided so that the user can change the resistance value or the capacitance value, and the user can adjust or designate the frequency of the sound waves output from the speaker 14. In addition, the resistance value or the capacitance value of the variable resistors R3 and R4 or the variable capacitance capacitor C2 may be automatically changed at a predetermined cycle. This prevents vermin from becoming accustomed to the ultrasonic waves.

The resistors R1 and R2 of the oscillation circuit 23 illustrated in FIG. 5 may be changed to variable resistors R3 and R4, and the capacitor C1 may be changed to a variable capacitance capacitor C2. Furthermore, each of the resistor R1, the resistor R2, and the capacitor C1 of the oscillation circuit 23 illustrated in FIG. 3 may be changed to a variable resistor or a variable capacitance capacitor.

The oscillation circuit 13 may be a circuit Wien bridge type or twin type oscillation circuit. The oscillation circuit 13 may be a Colpitts oscillation circuit or a Hartley oscillation circuit using an LC circuit. The oscillation circuit 13 may be a ring oscillator.

### Second Embodiment

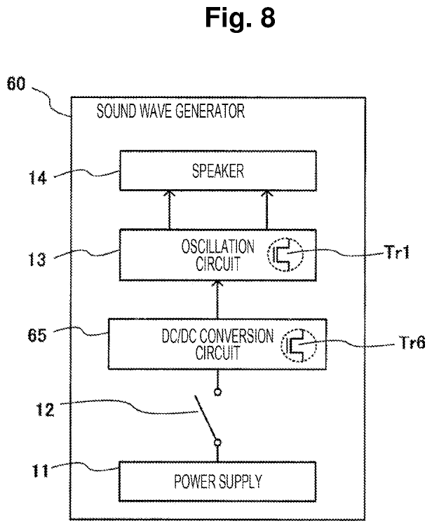

As illustrated in FIG. 8, a sound wave generator 60 according to a second embodiment includes a DC/DC conversion circuit 65 between the oscillation circuit 13 and the power supply 11 in addition to the power supply 11, the switch 12, the oscillation circuit 13, and the speaker 14 similar to those in the first embodiment. The circuit configuration of the oscillation circuit 13 is arbitrary as in the first embodiment. For example, the oscillation circuit 13 may be changed to an oscillation circuit 23, 33, or 43.

The DC/DC conversion circuit 65 boosts DC power output from the power supply 11 and input to the oscillation circuit 13. The oscillation circuit 13 operates with the DC power boosted and input. The circuit configuration of the DC/DC conversion circuit 65 is also arbitrary, but one or more organic transistors Tr6 using an organic semiconductor are also used in the DC/DC conversion circuit 65. The structure of the organic transistor Tr6 may be similar to the structure of the organic transistor Tr1.

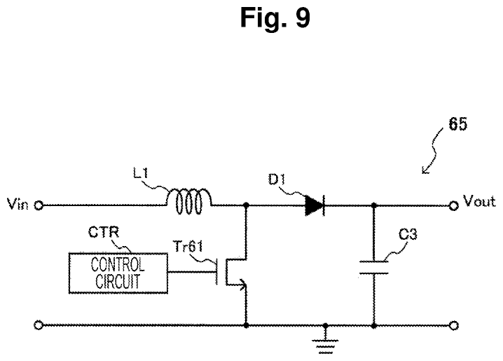

For example, as illustrated in FIG. 9, the DC/DC conversion circuit 65 includes a chopper type boosting circuit including a choke coil L1, a diode D1, a capacitor C1, an N-type organic transistor Tr61, and a control circuit CTR. The control circuit CTR operates with power from the power supply 11 and turns on and off the organic transistor Tr61 at a predetermined cycle. Accordingly, energy is stored and released by the choke coil L1, and Vin, which is the input voltage from the power supply 11, is boosted and output as Vout. A transistor may be used in the control circuit CTR, and the transistor is also desirably an organic transistor. The organic transistor and the organic transistor Tr61 correspond to the organic transistor Tr6. By using the organic transistor Tr6, the environmental load is reduced as in the case of using the organic transistor Tr1.

In the sound wave generator 60, the DC/DC conversion circuit 65 can boost the DC power from the power supply 11 and operate the oscillation circuit 13 with the boosted DC power. Accordingly, a voltage higher than that in the first embodiment is input to the oscillation circuit 13. As a result, the oscillation circuit 13 can oscillate an electrical signal having a larger amplitude than that of the first embodiment, and a high voltage can be applied to the speaker 14.

As described above, PZT and PVDF are conceivable as materials of the piezoelectric body 14C of the speaker 14. Here, PVDF has a lower environmental load than PZT. On the other hand, PVDF has lower piezoelectric performance than PZT, and when the same sound pressure is to be generated, PVDF is required to have a higher voltage than PZT. In the sound wave generator 60, since a high voltage can be applied to the speaker 14 by the DC/DC conversion circuit 65, a sufficient sound pressure can be obtained even if PVDF is used as the material of the piezoelectric body 14C of the speaker 14. Therefore, the sound wave generator 60 according to the present embodiment has an effect of being able to generate sound waves having a sufficient sound pressure even if PVDF is employed to reduce the environmental load.

At least one organic transistor Tr1 among one or more organic transistors Tr1 used in the oscillation circuit 13 and at least one organic transistor Tr6 among one or more organic transistors Tr6 used in the DC/DC conversion circuit 65 may be P-type or N-type and the same type. In this case, as the former organic transistor Tr1, a transistor having a higher operating voltage than that of the latter organic transistor Tr6 may be employed. The operating voltage is a potential difference between the gate and the source or between the gate and the drain necessary for turning on the organic transistor Tr1 or Tr6. In the sound wave generator 6o, since the voltage boosted by the DC/DC conversion circuit 65 is input to the oscillation circuit 13, the voltage applied to the organic transistor Tr1 also increases. Therefore, an organic transistor having a high operating voltage is preferably used as the organic transistor Tr1. In addition, by making the operating voltage of the organic transistor Tr6 of the DC/DC conversion circuit 65 lower than that of the organic transistor Tr1, the power consumption in the DC/DC conversion circuit 65 is reduced as compared with the case where the organic transistor Tr1 having a high operating voltage used in the oscillation circuit 13 is used in the DC/DC conversion circuit 65.

The at least one organic transistor Tr1 used in the oscillation circuit 13 and the at least one organic transistor Tr6 used in the DC/DC conversion circuit 65 may have the same structure formed of the same material. Even if the organic transistors have the same structure formed of the same material by mass production, for example, quality may vary. In particular, variations in operating voltage may occur. According to the above configuration, since the use of the organic transistor can be determined depending on the level of the operating voltage, the number of organic transistors that are not used and are discarded can be reduced. For example, in the manufacture of the sound wave generator 10, operating voltages of a plurality of organic transistors mass-produced by the same manufacturing process, that is, a plurality of organic transistors having the same structure formed of the same material are specified by measurement or the like. As a result of specification, among the plurality of organic transistors, an organic transistor having an operating voltage lower than a predetermined reference is employed as the organic transistor Tr6, and an organic transistor having an operating voltage higher than the predetermined reference is employed as the organic transistor Tr1. Accordingly, the number of organic transistors to be discarded can be reduced.

### Third Embodiment

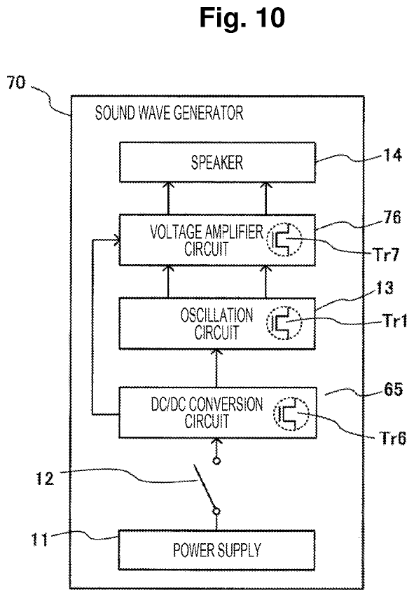

As illustrated in FIG. 10, in addition to the configuration of the sound wave generator 6o according to the second embodiment, a sound wave generator 70 according to a third embodiment includes a voltage amplifier circuit 76 that amplifies the voltage of the electrical signal output from the oscillation circuit 13 between the speaker 14 and the oscillation circuit 13.

The voltage amplifier circuit 76 operates with the power boosted by the DC/DC conversion circuit 65 and amplifies the voltage of the electrical signal output from the oscillation circuit 13 and input to the speaker 14. The circuit configuration of the voltage amplifier circuit 76 is also arbitrary, but one or more organic transistors Tr7 using an organic semiconductor are also used in the voltage amplifier circuit 76. The structure of the organic transistor Tr7 may be similar to the structure of the organic transistor Tr1.

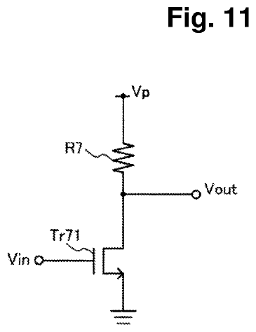

For example, as illustrated in FIG. 11, the voltage amplifier circuit 76 includes a grounded-source amplifier circuit including a resistor R7 and an N-type organic transistor Tr71. A voltage Vp boosted by the DC/DC conversion circuit 65 is applied to the voltage amplifier circuit 76 to operate. An electrical signal output from the oscillation circuit 13 is input to a gate of the organic transistor Tr71 as an input voltage Vin. The voltage amplifier circuit 76 inputs an electrical signal having a voltage Vout amplified by the organic transistor Tr71 to the speaker 14. The organic transistor Tr71 corresponds to the organic transistor Tr7. By using the organic transistor Tr7, the environmental load is reduced as in the case of using the organic transistor Tr1. Note that the voltage amplifier circuit 76 may include a differential amplifier circuit, an operational amplifier, and the like.

In the sound wave generator 70, the amplitude of the electrical signal output from the oscillation circuit 13 can be further increased by the voltage amplifier circuit 76, and a higher voltage can be applied to the speaker 14. Therefore, the sound wave generator 70 according to the present embodiment has an effect of being able to generate sound waves having a sufficient sound pressure even if PVDF is employed to reduce the environmental load.

At least one organic transistor Tr7 among one or more organic transistors Tr7 used in the voltage amplifier circuit 76 and at least one organic transistor Tr6 among one or more organic transistors Tr6 used in the DC/DC conversion circuit 65 may be P-type or N-type and the same type. In this case, as the former organic transistor Tr7, a transistor having a higher operating voltage than that of the latter organic transistor Tr6 may be employed. In the sound wave generator 70, since the voltage boosted by the DC/DC conversion circuit 65 is input to the voltage amplifier circuit 76, the voltage applied to the organic transistor Tr7 also increases. Therefore, an organic transistor having a high operating voltage is preferably used as the organic transistor Tr7. In addition, by making the operating voltage of the organic transistor Tr6 of the DC/DC conversion circuit 65 lower than that of the organic transistor Tr7, the power consumption in the DC/DC conversion circuit 65 is reduced as compared with the case where the organic transistor Tr7 having a high operating voltage used in the voltage amplifier circuit 76 is used in the DC/DC conversion circuit 65.

The at least one organic transistor Tr7 used in the voltage amplifier circuit 76 and the at least one organic transistor Tr6 used in the DC/DC conversion circuit 65 may have the same structure formed of the same material. Accordingly, similarly to the second embodiment, the number of organic transistors that are not used and are discarded can be reduced. For example, in the manufacture of the sound wave generator 10, operating voltages of a plurality of organic transistors mass-produced by the same manufacturing process, that is, a plurality of organic transistors having the same structure formed of the same material are specified by measurement or the like. As a result of specification, among the plurality of organic transistors, an organic transistor having an operating voltage lower than a predetermined reference is employed as the organic transistor Tr6, and an organic transistor having an operating voltage higher than the predetermined reference is employed as the organic transistor Tr7. Accordingly, the number of organic transistors to be discarded can be reduced.

### Fourth Embodiment

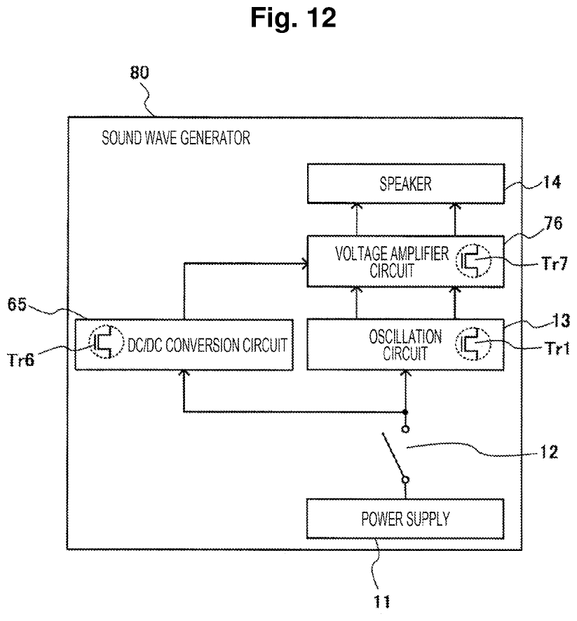

As illustrated in FIG. 12, a sound wave generator 70 according to a fifth embodiment is different from the sound wave generator 70 according to the fourth embodiment in the arrangement of each circuit. Specifically, in the sound wave generator 70, the DC/DC conversion circuit 65 is arranged in parallel with the oscillation circuit 13 with respect to the power supply 11 to the switch 12. The DC power boosted by the DC/DC conversion circuit 65 is not supplied to the oscillation circuit 13 but is supplied only to the voltage amplifier circuit 76. The voltage amplifier circuit 76 operates with the power boosted by the DC/DC conversion circuit 65 and amplifies the voltage of the electrical signal output from the oscillation circuit 13 and input to the speaker 14. For example, the voltage boosted by the DC/DC conversion circuit 65 is applied to the voltage amplifier circuit 76 as the voltage Vp in FIG. 11.

Also in the fourth embodiment, by using the organic transistors Tr1, Tr6, and Tr7, the environmental load is reduced as described above. Further, in the sound wave generator 80, the amplitude of the electrical signal output from the oscillation circuit 13 can be increased by the voltage amplifier circuit 76, and a high voltage can be applied to the speaker 14. Therefore, the sound wave generator 80 according to the present embodiment has an effect of being able to generate sound waves having a sufficient sound pressure even if PVDF is employed to reduce the environmental load.

At least one organic transistor Tr7 among one or more organic transistors Tr7 used in the voltage amplifier circuit 76 and at least one organic transistor Tr6 among one or more organic transistors Tr6 used in the DC/DC conversion circuit 65 may be P-type or N-type and the same type. In this case, as the former organic transistor Tr7, a transistor having a higher operating voltage than that of the latter organic transistor Tr6 may be employed. In the sound wave generator 80, since the voltage boosted by the DC/DC conversion circuit 65 is input to the voltage amplifier circuit 76, the voltage applied to the organic transistor Tr7 also increases. Therefore, an organic transistor having a high operating voltage is preferably used as the organic transistor Tr7. In addition, by making the operating voltage of the organic transistor Tr6 of the DC/DC conversion circuit 65 lower than that of the organic transistor Tr7, the power consumption in the DC/DC conversion circuit 65 is reduced as compared with the case where the organic transistor Tr7 having a high operating voltage used in the voltage amplifier circuit 76 is used in the DC/DC conversion circuit 65.

The at least one organic transistor Tr7 used in the voltage amplifier circuit 76 and the at least one organic transistor Tr6 used in the DC/DC conversion circuit 65 may have the same structure formed of the same material. Accordingly, similarly to the second embodiment, the number of organic transistors that are not used and are discarded can be reduced. For example, in the manufacture of the sound wave generator 10, operating voltages of a plurality of organic transistors mass-produced by the same manufacturing process, that is, a plurality of organic transistors having the same structure formed of the same material are specified by measurement or the like. As a result of specification, among the plurality of organic transistors, an organic transistor having an operating voltage lower than a predetermined reference is employed as the organic transistor Tr6, and an organic transistor having an operating voltage higher than the predetermined reference is employed as the organic transistor Tr7. Accordingly, the number of organic transistors to be discarded can be reduced.

At least one organic transistor Tr7 among one or more organic transistors Tr7 used in the voltage amplifier circuit 76 and at least one organic transistor Tr1 among one or more organic transistors Tr1 used in the oscillation circuit 13 may be P-type or N-type and the same type. In this case, as the former organic transistor Tr7, a transistor having a higher operating voltage than that of the latter organic transistor Tr1 may be employed. By making the operating voltage of the organic transistor Tr1 of the oscillation circuit 13 lower than that of the organic transistor Tr7, the power consumption in the oscillation circuit 13 is reduced as compared with the case where the organic transistor Tr7 having a high operating voltage used in the voltage amplifier circuit 76 is used in the oscillation circuit 13.

The at least one organic transistor Tr7 used in the voltage amplifier circuit 76 and the at least one organic transistor Tr1 used in the oscillation circuit 13 may have the same structure formed of the same material. Accordingly, similarly to the second embodiment, the number of organic transistors that are not used and are discarded can be reduced. For example, in the manufacture of the sound wave generator 10, operating voltages of a plurality of organic transistors mass-produced by the same manufacturing process, that is, a plurality of organic transistors having the same structure formed of the same material are specified by measurement or the like. As a result of specification, among the plurality of organic transistors, an organic transistor having an operating voltage lower than a predetermined reference is employed as the organic transistor Tr1, and an organic transistor having an operating voltage higher than the predetermined reference is employed as the organic transistor Tr7. Accordingly, the number of organic transistors to be discarded can be reduced.

### Modifications

The embodiments of the present invention are not limited to the above embodiments, and various embodiments can be taken. In particular, each of the above embodiments may be modified. Hereinafter, modifications will be exemplified. For example, the sound waves emitted by the sound wave generator 10 or the like may not be ultrasonic waves but may be sound waves having a frequency less than the ultrasonic waves. In addition, the sound wave generator 10 or the like may be a device that emits sound waves having a predetermined frequency that chases away insect pests such as mosquitoes, moths, or cockroaches instead of or in addition to chasing away vermin. The sound wave generator 10 and the like may be configured to be used for applications other than vermin or insect pest control. The sound wave generator 10 and the like may be configured to simultaneously or sequentially generate a plurality of types of sound waves having different frequencies. Each element such as the resistor R1 and the capacitor C1 can be implemented with a chip resistor or a chip capacitor. Further, a transistor may be used as the resistor R1 or the like. In this case, the transistor is preferably an organic transistor.

### Significance of Using Organic Transistor in Each of Above Embodiments

In recent years, a vermin or the like repelling device that chases away vermin, insect pests, or both (hereinafter referred to as vermin or the like) using ultrasonic waves has been developed. This repelling device is a device that generates sound waves having a high frequency audible only to vermin or the like at a high sound pressure and applies stress to the vermin or the like, thereby driving the vermin or the like out of the place. The repelling device using sound waves has less influence on the human body and the environment than an exterminating method in which a chemical substance is sprayed. The application target of the repelling device using sound waves is various insects such as mosquitoes, moths, and cockroaches, and animals such as crows, wild boars, deer, monkeys, masked palm civets, bears, and mice. Although there are frequencies that are said to be particularly effective for specific insects and animals, in a general repelling device, it is said that there is an effect when a sound wave of 25 KHz or more is generated at a high sound pressure and the frequency is temporally changed.

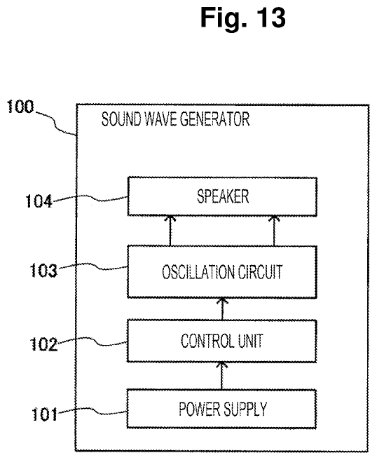

FIG. 13 illustrates a configuration example of a general sound wave generator 100 as a vermin or the like repelling device used for repelling vermin or the like of an ultrasonic system. The sound wave generator 100 includes a power supply 101, a control unit 102, an oscillation circuit 103, and a speaker 104. The power supply 101 is a battery and supplies power to the sound wave generator 100. The control unit 102 performs generation control of sound waves and setting of a generation frequency and corresponds to the switch 12 in the above embodiment. The oscillation circuit 103 oscillates an electrical signal having a target frequency in accordance with an instruction from the control unit 102. The speaker 104 converts the electrical signal oscillated by the oscillation circuit 103 into sound waves and emits the sound waves.

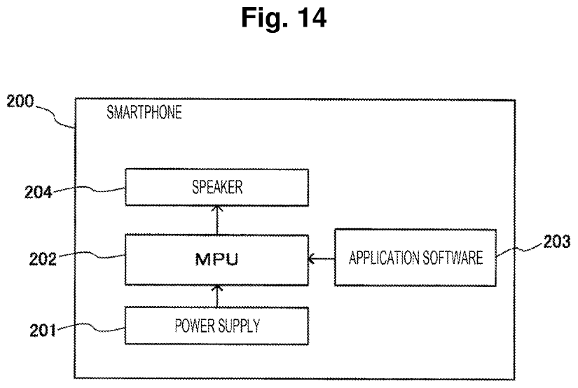

FIG. 14 illustrates a configuration example when the sound wave generator 100 is configured by a smartphone 200. The smartphone 200 includes a power supply 201 including a battery, a micro processing unit (MPU) 202, application software 203 stored in a storage unit (not illustrated), and a speaker 204. In the smartphone 200, the MPU 202 that executes the application software 203 functions as the control unit 102 and the oscillation circuit 103. When the ultrasonic waves are generated in the smartphone 200, the MPU 202 executes the application software 203 to generate an electrical signal having a predetermined frequency according to the setting of the user. The generated electrical signal is converted into ultrasonic waves by the speaker 204 and output.

Since a sound wave generator as a device for repelling vermin or the like of an ultrasonic system is sometimes used when a person enters a mountainous region, it is required to have portability and to be made of an environmentally friendly material, that is, a material having a low environmental load. The repelling device formed of a smartphone has portability, but is not made of an environmentally friendly material because a rare metal or the like is used. In addition, as disclosed in the above-mentioned Patent Literature 1 and Non Patent Literature 1, in a case where the repelling device for vermin or the like is configured as a dedicated device, although the portability depends on mounting, the electronic component generally contains a rare metal, and it is a problem that the electronic component is not made of an environmentally friendly material.

In each of the above embodiments, by using an organic transistor that is environmentally friendly, it is possible to reduce the amount of rare metals or the like having a large environmental load used. Furthermore, in the organic transistor, since it is not necessary to use a metal such as tungsten as an electrode, the organic transistor has a small environmental load also in this respect. Furthermore, the organic transistor can be formed to have flexibility or is formed to be lighter than a conventional inorganic semiconductor. Accordingly, the portability of the sound wave generator of each of the above embodiments using the organic transistor is improved. All the transistors used in the sound wave generator may not be organic transistors. Even if only some of the transistors are organic transistors, the use of rare metals for that amount and the like will be eliminated, so that the environmental load will be reduced.

### REFERENCE SIGNS LIST

10 Sound wave generator
11 Power supply
12 Switch
13 Oscillation circuit
14 Speaker
14C Piezoelectric body
Tr1 Organic transistor
F2 Organic semiconductor layer
60 Sound wave generator
65 DC/DC conversion circuit
Tr6 Organic transistor
70 Sound wave generator
76 Voltage amplifier circuit
Tr7 Organic transistor
80 Sound wave generator

1.-7. (canceled)

8. A sound wave generator comprising:
an oscillation circuit configured to oscillate an electrical signal for sound waves, the oscillation circuit comprising a first organic transistor comprising a first organic semiconductor; and
a speaker configured to convert the electrical signal oscillated by the oscillation circuit into the sound waves and output the sound waves.

9. The sound wave generator according to claim 8, further comprising a DC/DC conversion circuit configured to boost DC power output from a DC power supply, the DC/DC conversion circuit comprising a second organic transistor comprising a second organic semiconductor, wherein the oscillation circuit is configured to operate with the DC power boosted by the DC/DC conversion circuit and oscillate the electrical signal.

10. The sound wave generator according to claim 9, wherein:
the first organic transistor of the oscillation circuit and the second organic transistor of the DC/DC conversion circuit are a same type, wherein the same type is N-type or P-type; and
the first organic transistor of the oscillation circuit operates at a higher operating voltage than the second organic transistor of the DC/DC conversion circuit.

11. The sound wave generator according to claim 10, wherein the first organic transistor of the oscillation circuit and the second organic transistor of the DC/DC conversion circuit have a same structure comprising a same material.

12. The sound wave generator according to claim 8, further comprising:
a DC/DC conversion circuit configured to boost DC power output from a DC power supply, the DC/DC conversion circuit comprising a second organic transistor comprising a second organic semiconductor; and
a voltage amplifier circuit configured to operate with the DC power boosted by the DC/DC conversion circuit, to amplify a voltage of the electrical signal output from the oscillation circuit, and to output the voltage amplified to the speaker, the voltage amplifier circuit comprising a third organic transistor comprising a third organic semiconductor.

13. The sound wave generator according to claim 12, wherein:
the third organic transistor of the voltage amplifier circuit and the second organic transistor of the DC/DC conversion circuit are a same type, wherein the same type is N-type or P-type; and
the third organic transistor of the voltage amplifier circuit operates at a higher operating voltage than the second organic transistor of the DC/DC conversion circuit.

14. The sound wave generator according to claim 13, wherein the third organic transistor of the voltage amplifier circuit and the second organic transistor of the DC/DC conversion circuit have a same structure comprising a same material.

15. The sound wave generator according to claim 8, wherein the first organic transistor comprises:
a gate electrode on a substrate;
a gate insulating film on the gate electrode and the substrate;
an organic semiconductor layer comprising the first organic semiconductor on the gate insulating film; and
a source electrode and a drain electrode on the organic semiconductor layer.

16. The sound wave generator according to claim 15, wherein the first organic semiconductor comprises pentacene, naphthacene, fullerene, or a naphthalenetetracarboxylic acid diimide derivative (NTCDI).

17. A sound wave generator comprising:
a DC power supply comprising a battery;
an oscillation circuit configured to oscillate an electrical signal for sound waves, the oscillation circuit comprising a plurality of first organic transistors each comprising a first organic semiconductor; and
a speaker configured to convert the electrical signal oscillated by the oscillation circuit into the sound waves and output the sound waves.

18. The sound wave generator according to claim 17, further comprising a DC/DC conversion circuit configured to boost DC power output from the DC power supply, the DC/DC conversion circuit comprising a plurality of second organic transistors each comprising a second organic semiconductor, wherein the oscillation circuit is configured to operate with the DC power boosted by the DC/DC conversion circuit and oscillate the electrical signal.

19. The sound wave generator according to claim 18, wherein:
a portion of the plurality of first organic transistors of the oscillation circuit and a portion of the plurality of second organic transistors of the DC/DC conversion circuit are a same type, wherein the same type is N-type or P-type; and
each of the plurality of first organic transistors of the oscillation circuit operate at a higher operating voltage than each of the plurality of second organic transistors of the DC/DC conversion circuit.

20. The sound wave generator according to claim 19, wherein the portion of the plurality of first organic transistors of the oscillation circuit and the portion of the plurality of second organic transistors of the DC/DC conversion circuit have a same structure comprising a same material.

21. The sound wave generator according to claim 17, further comprising:
a DC/DC conversion circuit configured to boost DC power output from the DC power supply, the DC/DC conversion circuit comprising a plurality of second organic transistors each comprising a second organic semiconductor; and
a voltage amplifier circuit configured to operate with the DC power boosted by the DC/DC conversion circuit, to amplify a voltage of the electrical signal output from the oscillation circuit, and to output the voltage amplified to the speaker, the voltage amplifier circuit comprising a plurality of third organic transistors each comprising a third organic semiconductor.

22. The sound wave generator according to claim 21, wherein:
a portion of the plurality of third organic transistors of the voltage amplifier circuit and a portion of the plurality of second organic transistors of the DC/DC conversion circuit are a same type, wherein the same type is N-type or P-type; and
each of the plurality of third organic transistors of the voltage amplifier circuit operates at a higher operating voltage than each of the plurality of second organic transistors of the DC/DC conversion circuit.

23. The sound wave generator according to claim 22, wherein the portion of the plurality of third organic transistors of the voltage amplifier circuit and the portion of the plurality of second organic transistors of the DC/DC conversion circuit have a same structure comprising a same material.

24. The sound wave generator according to claim 17, wherein each of the plurality of first organic transistors comprises:
a gate electrode on a substrate;
a gate insulating film on the gate electrode and the substrate;
an organic semiconductor layer comprising the first organic semiconductor on the gate insulating film; and
a source electrode and a drain electrode on the organic semiconductor layer.

25. The sound wave generator according to claim 24, wherein the first organic semiconductor comprises pentacene, naphthacene, fullerene, or a naphthalenetetracarboxylic acid diimide derivative (NTCDI).
